(19) United States
(12) Patent Application Publication
(10) Pub. No.: US 2008/0099860 A1
(43) Pub. Date: May 1, 2008

(54) SEMICONDUCTOR ARRAY AND METHOD FOR MANUFACTURING A SEMICONDUCTOR ARRAY

(76) Inventor: Alida Wuertz, Marbach (DE)

Correspondence Address: Muncy, Geissler, Olds & Lowe, PLLC, P.O. BOX 1364, FAIRFAX, VA, 22038-1364, US

(21) Appl. No.: 11/934,073

(22) Filed: Nov. 1, 2007

Related U.S. Application Data
(60) Provisional application No. 60/855,750, filed on Nov. 1, 2006.

(30) Foreign Application Priority Data
Nov. 2, 2006 (DE) DE 102006051597

(51) Int. Cl. H01L 29/84; H01L 21/306

(52) U.S. Cl. 257/415; 438/52; 257/E29.324; 257/E21.219; 257/619

(57) ABSTRACT

a semiconductor Array and method for Manufacturing a semiconductor array is provided that includes a substrate, an element layer of a single-crystal semiconductor material, an isolation layer that is formed between the substrate and the element layer and isolates the element layer from the substrate, a number of elements that are formed in the element layer, a trench structure that is adjacent to the isolation layer and that is filled with a filling, to isolate at least one element of the number of elements within the element layer in a lateral direction, whereby the filling has a dielectric, and a self-supporting microstructure that is formed in a structure region defined by the trench structure.

This nonprovisional application claims priority to German Patent Application No. DE 102006051597, which was filed in Germany on Nov. 2, 2006, and to U.S. Provisional Application No. 60/855,750, which was filed on Nov. 1, 2006, and which are both herein incorporated by reference.

### BACKGROUND OF THE INVENTION

1. Field of the Invention

The present invention relates to a semiconductor array and to a method for manufacturing a semiconductor array.

2. Description of the Background Art

A method for manufacturing a microstructure (MEMS) is known from “Laminated High-Aspect-Ratio Microstructures in a Conventional CMOS Process,” G. K. Fedder et al., in IEEE Micro Electro Mechanical Systems, p. 13, Workshop (San Diego, Calif.) 11-15 Feb. 1996. In this case, microstructures are integrated together with CMOS structures of a standard CMOS process. The microstructure is produced in the CMOS process by a combination of aluminum layers, silicon dioxide layers, and silicon nitride layers. The silicon substrate, which serves as the sacrificial material, is etched first anisotropically and then isotropically in the region of the microstructure, so that the microstructure is undercut. The metal layers and the dielectric layers, which are normally used for electrical connection for the CMOS structures, have a dual function in the structuring of the microstructure. A similar manufacturing process with isotropic etching of a silicon substrate is disclosed in U.S. Pat. No. 5,717,631.

An improvement of this microstructure manufacturing, compatible with a CMOS process, is said to have been disclosed in “Post-CMOS Processing for High-Aspect-Ratio Integrated Silicon Microstructures”, H. Xie et al., IEEE/ASME Journal of Microelectromechanical Systems, Vol. 11, Issue 2, pp. 93-101, April 2002; here, the silicon substrate is thinned locally from the back of the wafer by anisotropic etching. The microstructure is then exposed by anisotropic etching from the front of the wafer.

Microstructures on an SOI substrate (Silicon On Insulator) are also known from U.S. Patent No. 2002/0,127,822 A1 and U.S. Pat. No. 6,528,887 B2. The previously buried isolation layer of the SOI structure functions as the sacrificial layer and is removed by etching to expose the microstructure. Measures are provided, furthermore, that are to prevent an unwanted adherence of the microstructure to the surface of the substrate. In German patent publication DE 100 17 422 A1, a buried oxide layer also acts as a sacrificial oxide, which is etched to expose the polycrystalline silicon microstructure. The polycrystalline silicon microstructure is structured by etched trenches in the polycrystalline silicon.

### SUMMARY OF THE INVENTION

It is therefore an object of the present invention to provide a semiconductor array having a self-supporting microstructure, the electrical or mechanical properties being improved as much as possible.

Hence, a semiconductor array is provided, which has a substrate, an element layer made of single-crystal semiconductor material, and an isolation layer. The isolation layer is formed between the substrate and the element layer and isolates the element layer from the substrate. This type of arrangement is also called SOI (Silicon On Insulator) or SOS (Silicon On Sapphire). In this case, the isolation layer is preferably made of a dielectric, such as silicon dioxide. The substrate is made, for example, from a semiconductor material. The element layer and/or the substrate advantageously have silicon.

The semiconductor array furthermore has a number of elements which are formed in the element layer. The single element or the plurality of elements is preferably made in a standard process for manufacturing MOSFET, DMOS field-effect transistors, and/or bipolar transistors. The plurality of elements in this case is preferably connected into a circuit for controlling an actuator and/or in a measuring circuit for measuring a sensor signal of a sensor.

Furthermore, the semiconductor array has a trench structure. The trench structure is adjacent to the isolation layer. The trench structure is filled with a filling. The filling has a dielectric for isolation. It is possible that the filling has, in addition, other materials such as polycrystalline silicon. The isolation effect of the dielectric makes it possible to isolate at least one element, but typically a plurality of elements within the element layer in the lateral direction. This type of trench structure has a number of particularly deep trenches, which together form the trench structure. Because the at least one element is isolated by the isolation layer from the substrate in the vertical direction as well, the at least one element is advantageously isolated on all sides in a box and connected electrically only via the terminals. In this case, as is conventional in semiconductor production, the lateral direction is understood to be a direction within a wafer plane and the vertical direction into a wafer depth, perpendicular to the wafer plane.

Furthermore, the semiconductor array has a self-supporting microstructure. This type of arrangement can also be formed as a MEMS (Micro-Electro-Mechanical System). MEMS is in particular the combination of at least one mechanical element forming the self-supporting microstructure and electronic circuits on a substrate or chip. The self-supporting microstructure, in this case, is preferably a sensor and/or an actuator and/or part of an electronic or electromechanical element.

Self-supporting means the realization of a microstructure, when it is not adjacent at least in areas to another solid material of the semiconductor array. The microstructure for fulfilling its function is preferably not supported by additional external load-receiving elements. The self-supporting microstructure is preferably mounted fixedly in the material of the semiconductor array at least on one side. Alternatively or in combination, other mountings (fixed bearing/movable bearing) can also be provided.

The self-supporting microstructure is formed in a structure region defined by the trench structure. The structure region is limited for this purpose by the trench structure preferably at least laterally within the element layer. The trench structure, therefore, synergetically to the function of isolating the at least one element, has the function of defining the structure region for the self-supporting microstructure, so that the self-supporting microstructure is therefore not formed outside the structure region defined by the trench structure. Therefore, the structure region is the region on the semiconductor chip in which the self-supporting microstructure is formed. The self-supporting microstructure is positioned by this definition relative to the trench structure. The limits of the structure region are specified preferably at least in the lateral direction by the definition by means of the trench structure. The trench structure preferably defines a space at least in lateral direction, the self-supporting microstructure being exposed and/or movable within this space.

The self-supporting microstructure is formed as movable in an embodiment variant. For example, the movable self-supporting microstructure has the form of a cantilever arm, which has only one support. This type of cantilever arm can also be called a cantilever. During movement this is subjected to pushing, torsion, or flexure. The support here, for example, is a restraint in which all six degrees of freedom are fixed. For appropriate movement, the movable self-supporting microstructure is preferably made elastic at least in sections.

According to a preferred further development, a number of openings are provided in the element layer. In this case, at least one opening of the number of openings is formed within the structure region and limited by the trench structure. To form the at least one opening, the single-crystal semiconductor material of the element layer is preferably removed within the structure region. The trench structure consequently has another synergetic function for limiting the opening. In this case, this limitation is directed to the at least one element.

Another advantageous development provides that the self-supporting microstructure is formed within a hermetically encapsulated cavity. Here, the cavity is closed by a capping layer. In an embodiment of this development, the cavity is formed at least partially by the at least one opening within the structure region. The capping layer preferably has a dielectric. In embodiment variants, the capping layer can be formed by a bonded cap wafer or a deposited layer.

According to an embodiment, the self-supporting microstructure is displaceable in the lateral direction. It is preferably provided in this case that the displacement of the self-supporting microstructure in the lateral direction is limited by the trench structure. The trench structure advantageously forms at least one mechanical stop for the self-supporting microstructure. Alternatively or in combination, a stop can also be formed outside of the element layer in that, for example, the stop is formed by a dielectric region or a metal trace above the element layer.

According to another embodiment, which may also be combined with the first embodiment, it is provided that the self-supporting microstructure is displaceable in the vertical direction. It is preferably provided here that the self-supporting microstructure is displaceable in the vertical direction into at least one opening of the number of openings. An advantageous embodiment of the second development variant provides that the vertical displacement is limited by the isolation layer or the element layer. The isolation layer or the element layer advantageously forms at least one mechanical stop for the self-supporting microstructure.

In another embodiment, the semiconductor array has traces. The traces are preferably formed in a number of conduction levels. Advantageously, the traces have a metal and/or a silicide and/or a doped semiconductor material, such as, for example, polycrystalline silicon. Several traces are structured to connect the number of elements. At least one trace of the traces is structured as an electrode of the self-supporting microstructure. For this purpose, the trace structured as an electrode is preferably disposed on or in the self-supporting microstructure. It is also possible to form the microstructure to include a conductive electrode in order to realize, for example, a self-supporting trace as a safety fuse. It is also preferable for the electrode to be electrically connected to the at least one element via a trace. The self-supporting microstructure can advantageously be moved by electrostatic forces. Alternatively to or in combination with the electrode, an integrated turn of a coil can also be formed by a trace within the self-supporting microstructure. In both cases, the self-supporting microstructure is preferably formed as an actuator or sensor.

In another embodiment, an electrode is provided for the self-supporting microstructure, which is formed within the structure region by a doped electrode region of the element layer. A dopant is preferably introduced into the electrode region even during the production of the at least one element. The electrode region is preferably limited by the trench structure. Alternatively, the electrode region can also be patterned by etching of the element layer.

According to another embodiment, the self-supporting microstructure has an elevation formed in the direction of the isolation layer. The elevation has a cross section tapering in the direction of the isolation layer. For example, the elevation is formed as a cone. Embodiments of the development variants provide additional elevations in other displacement directions. For example, an elevation can be formed with a tapering cross section in the direction of the trench structure.

Furthermore, the object of the invention is to provide a method for manufacturing a semiconductor array.

Accordingly, a method for manufacturing a semiconductor array is provided. First, a substrate, an element layer of a single-crystal semiconductor material, and an isolation layer, disposed between the substrate and the element layer, are formed.

In subsequent process steps, a number of elements are formed in the element layer. During or before the formation of elements, a filled trench structure is formed in the element layer. The filling has a dielectric for isolation. To form the trench structure, a number of preferably deep trenches are etched, in which dielectric is deposited.

In addition to isolating the at least one element, the trench structure defines a structure region. To define the structure region, the trench structure is advantageously formed geometrically by means of a lithographic creation of a mask and a subsequent etching step. This patterning produces, among others, the structure region and its limits within which a self-supporting microstructure is formed. The microstructure is therefore formed within this structure region defined by the trench structure. Preferably, the formation of the microstructure occurs after the formation of the number of elements advantageously in an additional module of a so-called back-end process (BEOL, Back End Of Line), so that the elements are advantageously no longer changed by the formation of the microstructure.

According to an embodiment, the semiconductor material of the element layer is etched to form the self-supporting microstructure within the structure region. To that end, layers above the element layer are removed first, for example, by etching and a surface of the element layer is exposed for the etch attack. It is preferred that the isolation layer is not or only slightly etched during the etching. It is preferred that the trench structure is not or only slightly etched during the etching. The etchant for the etching of the semiconductor material in the structure region acts selectively in such a way that the isolation layer acts as a vertical etch stop layer, and/or that the trench structure acts as a lateral etch stop layer.

In an embodiment, it is provided that to form the self-supporting microstructure an etching is masked by a mask. To form the mask, a mask layer is preferably patterned lithographically, whereby the material of the mask layer is selected with a suitable selectivity for a mask during the etch attack. The mask is thereby oriented to the trench structure. The orientation can occur here by adjusting the lithography of the mask to the lithography of the trench structure. For the adjustment, it is only necessary that the opening of the mask is positioned within the structure region defined by the trench structure and does not extend beyond the structure region. In this case; a width of an affected trench of the trench structure is preferably to have been formed broader than a possible misalignment of the two lithography steps. Alternatively to the adjustment of the two lithography steps, the orientation can in fact occur also self-adjusting, but it is sufficient when the opening is formed within a region enclosed by the trench structure, because an undercutting of the mask in the element layer is limited laterally by the trench structure.

According to another aspect, a shallow trench, filled with dielectric, is formed to form the microstructure within the structure region. This type of structure is also called an STI structure (Shallow Trench Isolation). Alternatively, a local oxide is formed to form the microstructure. The structure of a local oxide is also called a LOCOS structure (LOCal Oxidation of Silicon). The structure of the shallow trench, filled with dielectric, or of the local oxide is thereby formed with a cross section tapering in the direction of the substrate. The shallow trench, filled with dielectric, or the local oxide is preferably formed in the element layer of the structure region.

In another embodiment, it is provided that to form the self-supporting microstructure, a sacrificial layer, formed above and/or below the self-supporting microstructure, is removed to expose the self-supporting microstructure. In this regard, the sacrificial layer is not identical to the element layer or the isolation layer, but a separate layer formed for this purpose, which is removed for exposure, for example, by an etch attack. The sacrificial layer may have, for example, polycrystalline silicon, amorphous silicon, metal, or silicide. A structure of the sacrificial layer is preferably oriented to the trench structure.

According to another embodiment, an electrode region is doped in the element layer within the structure region. The doped electrode region in this case forms an electrode for the self-supporting microstructure. For doping, the dopant, for example, can be diffused in or implanted during the production of the number of elements.

The previously described development variants are especially advantageous both individually and in combination. In this regard, all development variants can be combined with one another. Some possible combinations are explained in the description of the exemplary embodiments shown in the figures. These possibilities of combinations of the development variants, depicted there, are not definitive, however.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1a to 1e are schematic sectional views of a part of a semiconductor array of a first exemplary embodiment at different times in the manufacturing process;

FIG. 1f is a schematic sectional view of a part of a semiconductor array of a second exemplary embodiment;

FIGS. 2a to 2g are schematic sectional views of a part of a semiconductor array of a third exemplary embodiment at different times in the manufacturing process;

FIGS. 3a to 3d are schematic sectional views of a part of a semiconductor array of a fourth exemplary embodiment at different times in the manufacturing process;

FIGS. 4a to 4c are schematic sectional views of a part of a semiconductor array of a fifth exemplary embodiment at different times in the manufacturing process; and

FIGS. 5a to 5e are schematic sectional views of a part of a semiconductor array of a sixth exemplary embodiment at different times in the manufacturing process.

### DETAILED DESCRIPTION

A self-supporting microstructure can be formed as a sensor or an actuator. A combined function as an actuator and sensor is also possible.

Alternatively or in combination, the self-supporting microstructure may be formed as an electronic or electromechanical element. Actuators may operate, for example, according to the operating principle of electric, magnetic, thermal, or flow energy. For example, an inductively operating electric motor, a thermal actuator, for example, a bimetal actuator, a hydraulic or pneumatic actuator, a piezo actuator, a magnetostrictive actuator, a rheological actuator, or a shape memory alloy may be used as an actuator.

If the self-supporting microstructure is used as a sensor, which can also be called a probe, one or more specified physical properties, such as, e.g., pressure, sound pressure, sound, acceleration, or force, for which there are many measuring principles available, can be determined by means of the self-supporting microstructure.

Therefore, for example, an oscillator, such as an extension vibrator, bending vibrator, or thickness vibrator, an inertial sensor, such as an acceleration sensor, a micromechanical switch, a micromechanical resonator, a pressure sensor membrane, a (vertical) mechanical differential capacitor, a mechanically movable mirror, a strain gauge, a bending beam, an optical switch, a micromechanical electric motor, a MEMS microphone, microvalve, safety fuse, one-time or repeatedly programmable memory, or a flow sensor can be realized by means of the self-supporting microstructure integrated on a semiconductor chip. These applications are not definitive but only preferred.

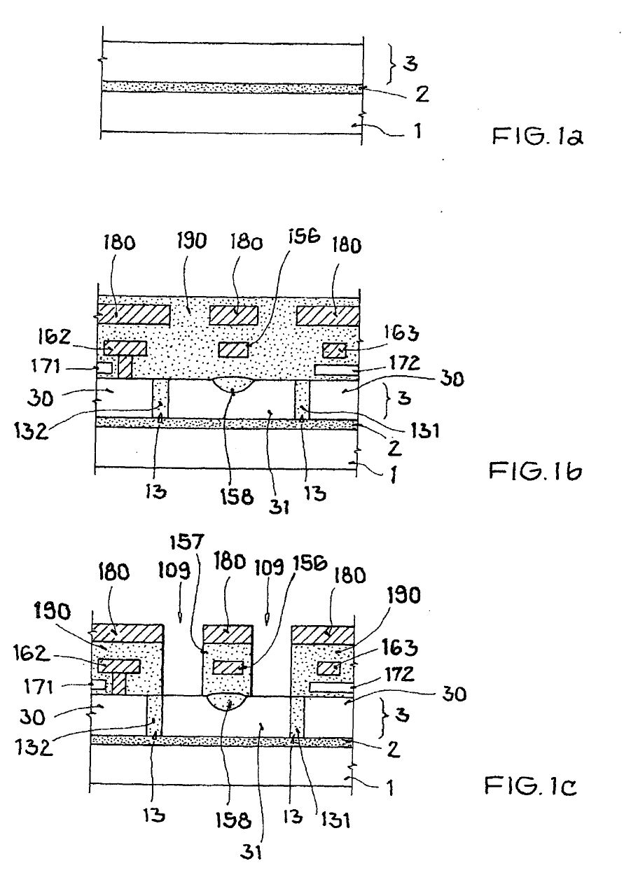

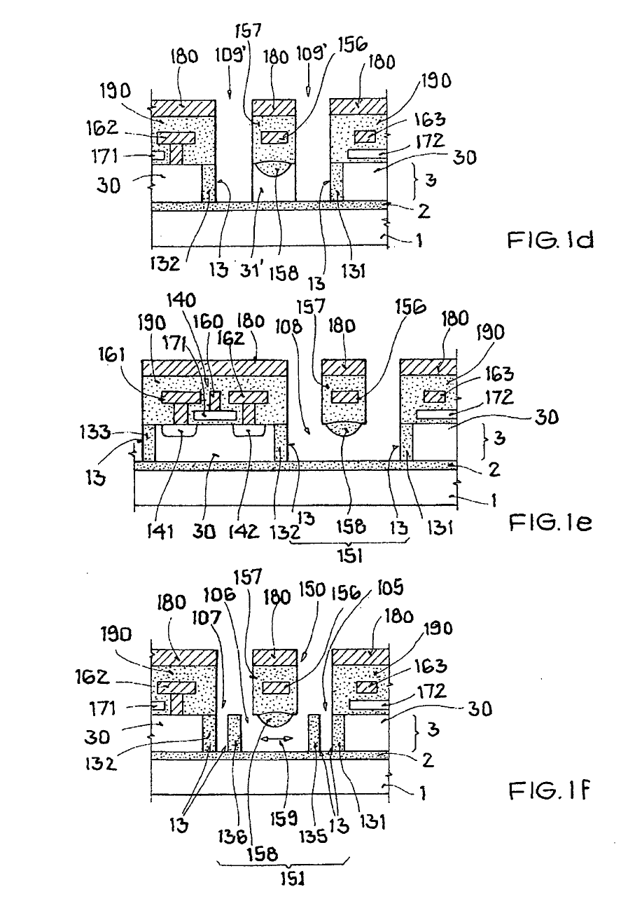

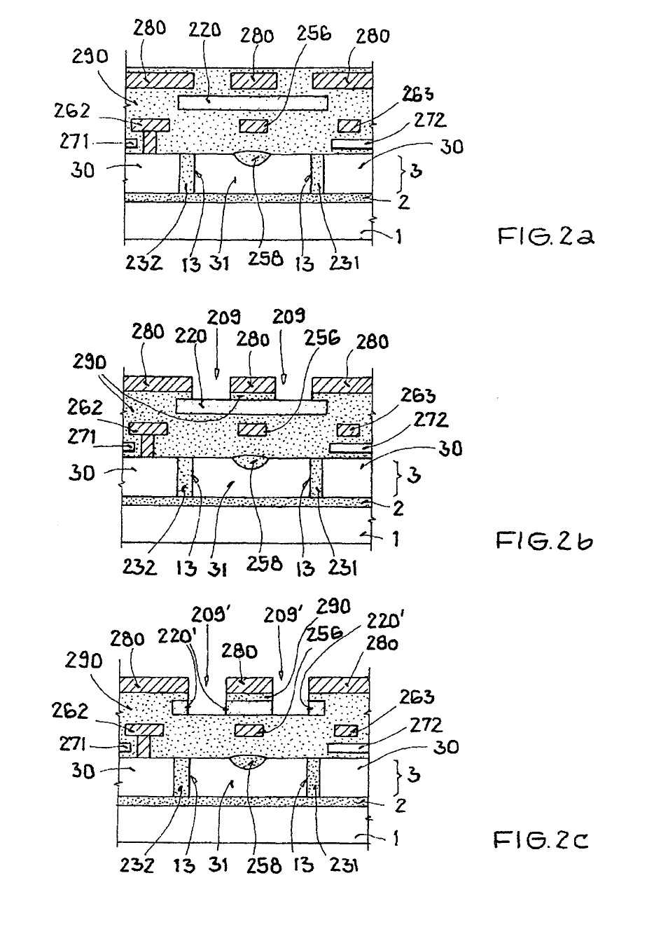

A first exemplary embodiment of a semiconductor array with a self-supporting microstructure 150 is shown schematically in FIG. 1e as a detailed sectional view through a semiconductor chip. In addition to self-supporting microstructure 150, the semiconductor array has a number of elements, whereby a field-effect transistor 140 is shown by way of example in FIG. 1e. The integration on a semiconductor chip, of course, permits formation of entire circuits, which are not shown in FIG. 1e merely for the sake of better understandability. At least one element (140) of the circuit is electrically connected to self-supporting microstructure 150. If the self-supporting microstructure is a sensor, the circuit is advantageously used for measuring signal evaluation or generation. For example, a resonant oscillation in rotation rate sensors can be excited by means of the circuit. If the self-supporting microstructure is an actuator, the circuit is advantageously used to drive the actuator.

The semiconductor array has an SOI structure (Silicon On Insulator) with a substrate 1 of silicon, with an isolation layer 2 of silicon dioxide, and with an element layer 3 of single-crystal silicon. Isolation layer 2 thereby isolates element layer 3 from substrate 1. Field-effect transistor 140 is formed in element layer 3 and in said layer has a drain semiconductor region 142 and a source semiconductor region 141. Drain semiconductor region 142 is connected to metal trace 162 and source semiconductor region 141 is connected to metal trace 161. Furthermore, a gate electrode 171 made of doped polycrystalline silicon is isolated by a gate oxide from the channel region of field-effect transistor 140. Gate electrode 171 is also connected by a metal trace 160. In addition to traces 160, 161, 162, for element 140, an additional trace 163 made of metal and a trace 172 made of polycrystalline silicon are indicated by way of example for other circuit elements (not shown).

Isolation layer 2 produces a dielectric, vertical isolation of element 140. Furthermore, a trench structure 13, which has a plurality of trenches 131, 132, and 133 filled with dielectric, is formed in element layer 3. In the exemplary embodiment of FIG. 1e, the trenches are filled in completely with the dielectric. Alternatively, for filling, trenches 131, 132, and 133 are coated with the dielectric in the edge regions and, for example, filled with polycrystalline silicon (not shown in FIG. 1e). Trenches 132 and 133 isolate element 140 here in the lateral direction, so that the semiconductor material of element 140 is encapsulated in a box of dielectric and thus isolated on all sides.

The two trenches 131 and 132 define a structure region 151 within which self-supporting microstructure 150 is formed. An opening 108, into which self-supporting microstructure 150 projects, is introduced in element region 3. Opening 108 is limited here by the two trenches 131 and 132, so that element 140 can be disposed in the immediate vicinity of said opening 108 and thereby in the immediate vicinity of self-supporting microstructure 150. This close proximity between element 140 and the microstructure enables very short lines. Short lines improve, among others, the noise immunity and reduce signal losses in this line.

Self-supporting microstructure 150 has an isolating dielectric 157 and an electrode 156 made of a metal trace. Furthermore, microstructure 150 has an elevation 158 in the direction of isolation layer 2. Said elevation 158 has a tapering cross section in the direction of the isolation layer. This formation of elevation 158 prevents the unintentional adherence of self-supporting microstructure 150 to isolation layer 2.

In an exemplary application example for self-supporting microstructure 150, this component is a membrane (not shown further) for measuring sound. For the measurement, for example, the capacitance between electrode 156 of self-supporting microstructure 150 and substrate 1 can be measured.

Different schematic sectional views at different times during the manufacture of the semiconductor array are shown in FIGS. 1a to 1e.

FIG. 1a shows the starting material with an SOI structure, substrate 1, isolation layer 2, and element layer 3 made of single-crystal silicon. FIG. 1b shows a view after processing for the manufacture of the elements. The so-called backend is completed before the exposure of the self-supporting microstructure (150, cf. FIG. 1e) occurs. A trench structure 13 with two trenches 131 and 132, filled with dielectric, is already provided during the processing for the manufacture of the elements for the later self-supporting microstructure (150, cf. FIG. 1e). Also provided is a small STI region 158, round at the bottom or tapering, (STI: Shallow Trench Isolation) as a later elevation to avoid so-called stiction effects between the self-supporting microstructure (150, cf. FIG. 1e) and isolation layer 2. It is possible to provide a plurality of STI regions analogous to what is shown in FIG. 1b. The number of trace levels with metallic traces 156, 162, 163, 180 or traces 172 of polycrystalline silicon can be varied as desired.

In FIG. 1c, the top patterned metal level 180 functions as a mask for an anisotropic oxide etching process, in which oxide 190 is etched anisotropically in the openings of mask 180 down to the surface of single-crystal silicon element layer 3. Alternatively to FIG. 1c, a further underlying metal level can be used as the mask, so that gradations can result. Self-supporting microstructures (150, cf. FIG. 1e) with a different thickness can also be produced by the use of different metal layers as etch masks. These may have, for example, different functions or be assigned to different measuring regions.

An anisotropic silicon etch process then occurs into a sacrificial region 31 of element layer 3. This is shown in FIG. 1d; here, after the anisotropic etching a residual sacrificial region 31′ remains below the later self-supporting microstructure (150, cf. FIG. 1e). This anisotropic silicon etching is used for prefabrication for the subsequent isotropic silicon etching. The etching time can be shortened in this way, because the lateral etching rate is usually lower than the vertical rate. The etching step of the anisotropic silicon etching is basically unnecessary, however, and can be replaced by a suitably longer isotropic etching of silicon 31. Trenches 131 and 132, filled with dielectric, act as a lateral stop layer for the isotropic silicon etching, so that etching into active semiconductor regions 30 of an adjacent element (140, cf. FIG. 1e) does not occur. The state after the isotropic silicon etching is shown in FIG. 1e. Top metal layer 180 can be removed totally or partially at a later time (not shown in FIG. 1e). The described method can be advantageously integrated into an SOI technology.

FIG. 1f shows another exemplary embodiment of a semiconductor array with a microstructure 150. In contrast to the exemplary embodiment of FIG. 1e, in FIG. 1f, two additional trenches 135 and 136, filled with dielectric, of trench structure 13 are provided, whereby the semiconductor material of element layer 3 is etched out between trenches 131, 132, 135, 136 by the (an)isotropic etching process, so that three openings 105, 106, and 107 are formed. The dielectric, originating from the two inner trenches 135 and 136, of trench structure 13 forms two stops and limits a lateral displacement 159 of self-supporting microstructure 150. The exemplary embodiment in FIG. 1f can have the advantage that a distance between two trenches of the trench structure defines the maximum displacement of the sensor/actuator and thus an overload of the self-supporting microstructure is avoidable.

In the exemplary embodiments in FIGS. 1e and 1f, substrate 1 is shown as a continuous layer. Alternatively, the substrate can also be structured (which is not shown in the figures), so that substrate regions isolated from one another can be produced. For this purpose, the substrate preferably has a conductive layer, which is structured into several conductive substrate regions isolated from one another. There is the possibility, furthermore, of connecting one or more substrate regions, for example, by through-hole plating, so that the potential vis-à-vis self-supporting microstructure 150 can also be set. By structuring substrate 1, it is also possible to remove said substrate locally below self-supporting microstructure 150 (not shown in FIGS. 1e and 1f). If the substrate is locally removed, making the self-supporting structure accessible from the substrate side is possible, for example, to couple the self-supporting structure magnetically to a soft magnetic material.

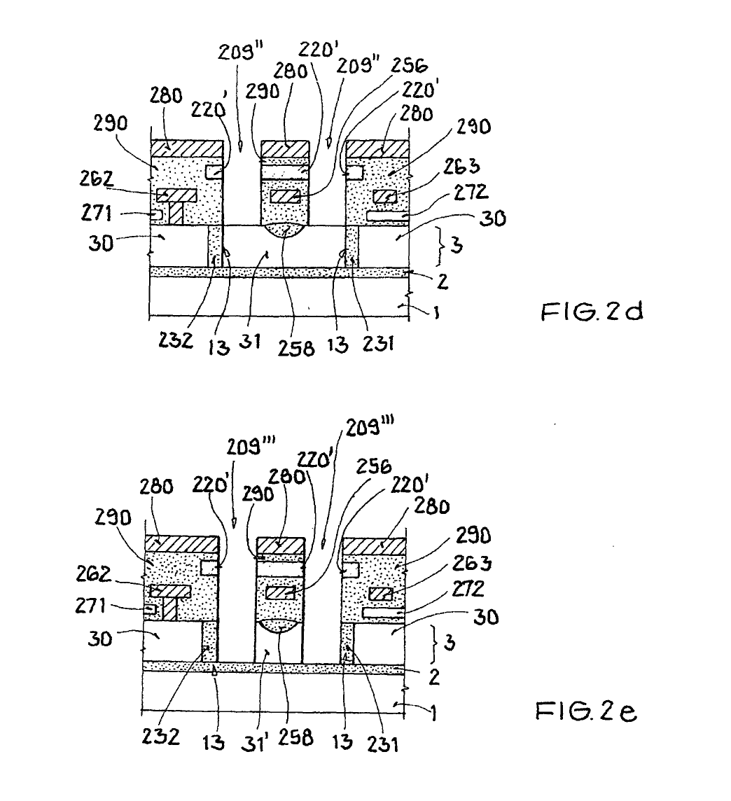

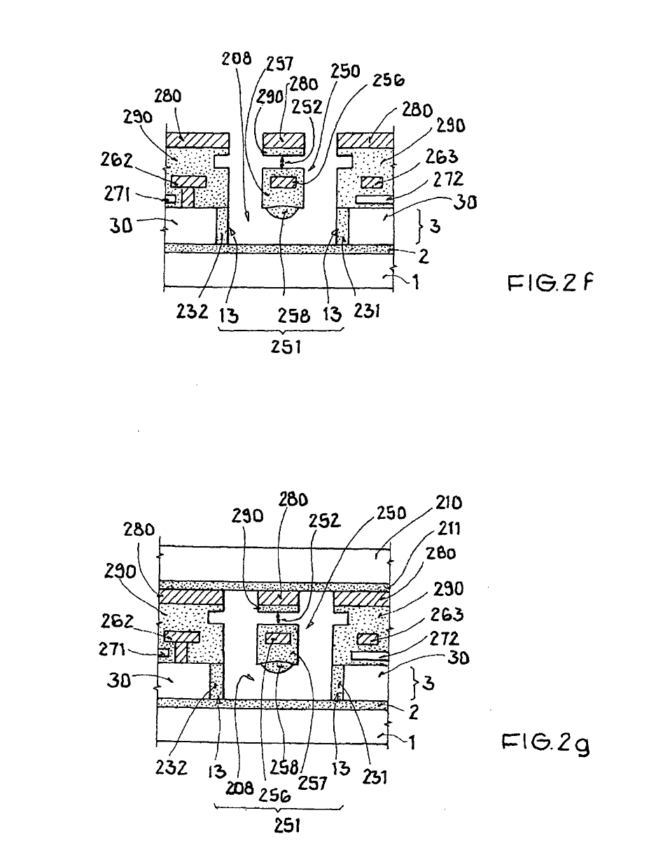

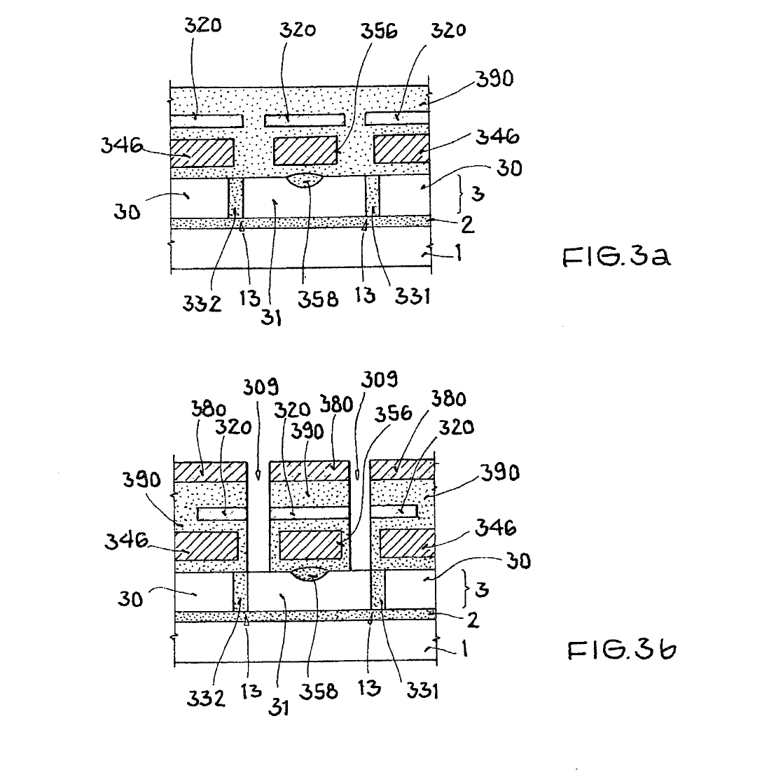

FIG. 2g shows another exemplary embodiment for a semiconductor array with a self-supporting microstructure 250. A substrate 1, an isolation layer 2, and an element layer 3 with a trench structure 13 with trenches 232 and 231 are again provided. Trench structure 13 delimits a structure region 251 in the lateral direction from active regions 30 in element layer 3. Within this structure region 251, the microstructure 250 is formed positioned to an opening 208. Microstructure 250 has an electrode 256, an isolating dielectric 257, and an elevation 258. Furthermore, traces 262, 263, 272 and a gate electrode 271 are isolated from one another by a dielectric 290.

In addition, a cap with a first capping layer 211 of silicon dioxide and a second capping layer 210 of silicon are provided, which are made as a cap wafer and bonded or glued to mask 280. Alternatively, a borosilicate glass wafer can be used as a cap. Covering layers 210, 211 make possible a hermetic encapsulation of opening 208 and protection of self-supporting microstructure 250 from contamination or protection from moisture. Furthermore, the cap enables a defined and/or constant pressure in opening 208. Self-supporting microstructure 250 can be used in this exemplary embodiment as an acceleration sensor by way of example. The maximum vertical displacement 252 is defined by a specified distance of self-supporting microstructure 250 to an oxide 290.

On the basis of FIGS. 2a to 2g, the manufacturing process for producing a semiconductor array is explained hereafter in greater detail according to FIG. 2g.

According to FIG. 2a, mask 280 is again provided. Furthermore, a silicon sacrificial layer 220, which may be single-crystal, polycrystalline, or amorphous, is formed below mask 280. Here, the temperature budget during the deposition must be considered, if deeper lying metal layers (262, 263, 256) are present.

According to FIG. 2b, in a first anisotropic etching step, which selectively etches dielectric 290, the surface of mask 280 and the surface of sacrificial layer 220 within openings 209 in mask 280 are exposed. The dielectric etching therefore stops at sacrificial layer 220.

According to FIG. 2c, an anisotropic silicon etching then occurs, which selectively etches opening 209′ in sacrificial layer 220 and leaves behind a sacrificial residual layer 220′ laterally adjacent to these openings 209′. The anisotropic silicon etching therefore stops at the surface of dielectric 290.

According to FIG. 2d, in a next process step, openings 209′ of FIG. 2c are deep-etched by an anisotropic dielectric etching step down to sacrificial region 31 of element layer 3 to deeper openings 209″.

An anisotropic silicon etch process then occurs into a sacrificial region 31 of element layer 3. This is shown in FIG. 2e; here, after the anisotropic etching a residual sacrificial region 31′ remains below the later self-supporting microstructure (250, cf. FIG. 2g). This anisotropic silicon etching is used for prefabrication for the subsequent isotropic silicon etching. The etching time can be shortened in this way, because the lateral etching rate is usually lower than the vertical rate. However, the etching step of the anisotropic silicon etching is basically unnecessary and can be replaced by a suitably longer isotropic etching of silicon 31. Trenches 231 and 232, filled with dielectric, act as a lateral stop layer for the isotropic silicon etching, so that etching into active semiconductor regions 30 of an adjacent element does not occur. The state after the isotropic silicon etching is shown in FIG. 2f.

Sacrificial residual layer 220′ is thereby also removed with the isotropic silicon etching. This removal defines two ribs lying one on top of another. The lower rib thereby is the desired self-supporting microstructure 250. Structuring of sacrificial layer 220, inserted above, allows formation of an elevation on the upper rib as well (not shown in FIG. 2f) to reduce, for example, the stiction effects.

The upper self-supporting rib can also be used synergetically in a double function for the encapsulation of self-supporting microstructure 250. For this purpose, this upper rib and other surface regions (mask regions 280 in the exemplary embodiment of FIG. 2g) are bonded to a cap wafer, forming capping layers 210 and 211. A glass wafer can also be used for this purpose as an alternative to an oxidized silicon wafer. It is advantageous in this case that the cap wafer need not be structured.

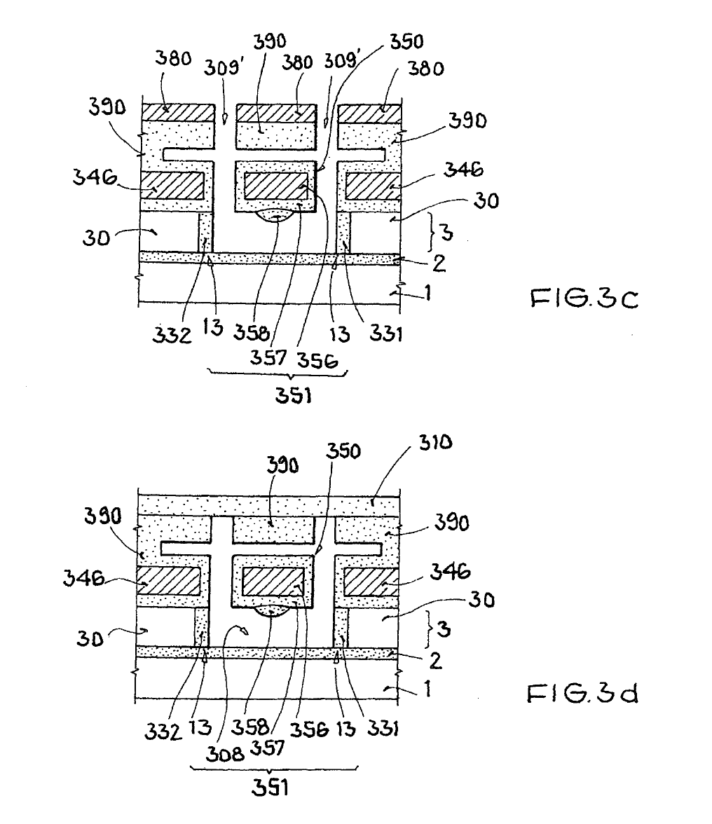

According to FIG. 3d, another exemplary embodiment for a semiconductor array with a self-supporting microstructure 350 is shown schematically in a sectional view.

A substrate 1, an isolation layer 2, and an element layer 3 with a trench structure 13 with trenches 332 and 331 are again provided. Trench structure 13 delimits a structure region 351 in the lateral direction from active regions 30 in element layer 3. Within this structure region 351, microstructure 350 is positioned to an opening 308. Microstructure 350 has an electrode 356 and an isolating dielectric 357. A semiconductor array is shown with two polycrystalline silicon layers 346 and 320, buried in oxide 390, as electrodes 346 or sacrificial layer 320. For example, a micromechanical resonator, in which a self-supporting rib 350 with polycrystalline silicon 356 as self-supporting microstructure 350 is driven electrostatically by the two laterally adjacent electrodes 346, is to be produced. To avoid short circuits, rib 350 has a dielectric isolation 357. Electrodes 346, distanced laterally from rib 350, are isolated by dielectric 390. The specific array and its electromechanical properties are thereby to be formed very flexibly, so that the exemplary embodiment of FIG. 3d represents only one of many possible realizations.

On the basis of FIGS. 3a to 3d, the manufacturing process for producing a semiconductor array is explained hereafter in greater detail according to FIG. 3d.

According to FIG. 3a, an array with polycrystalline silicon layers 320, 346, and 356 are used as the starting point. According to FIG. 3b, mask 380 is again provided. Sacrificial layer 320 of silicon is formed below mask 380.

In a first anisotropic etching step, which selectively etches dielectric 390, the etching is carried out through openings 309 in mask 380 down to a sacrificial region 31 of element layer 3. The dielectric etching therefore stops at sacrificial region 31. The edge regions of upper polycrystalline silicon layer 320, which is used later as sacrificial layer 320 to produce wafer-level encapsulation 310, are exposed in particular during the etching. As already explained in regard to FIG. 2, polysilicon layer 320 can also be structured first during the etching. In contrast, the exposure of the edge regions of sacrificial layer 320 according to FIG. 3b is a more rapid process.

A silicon etch process then occurs into a sacrificial region 31 of element layer 3. This is shown in FIG. 3c. This can in turn, include a combined anisotropic/isotropic etching or a purely isotropic etching. Trenches 331 and 332, filled with dielectric, act as a lateral stop layer for the silicon etching, so that etching into active semiconductor regions 30 of an adjacent element does not occur. The state after the isotropic silicon etching is shown in FIG. 3c.

Sacrificial layer 320 is thereby also removed with the isotropic silicon etching. This removal defines two ribs lying one on top of another. The lower rib thereby is the desired self-supporting microstructure 350. According to FIG. 3d, the closing of openings 309′ in the topmost layer occurs with the use of wafer bonding.

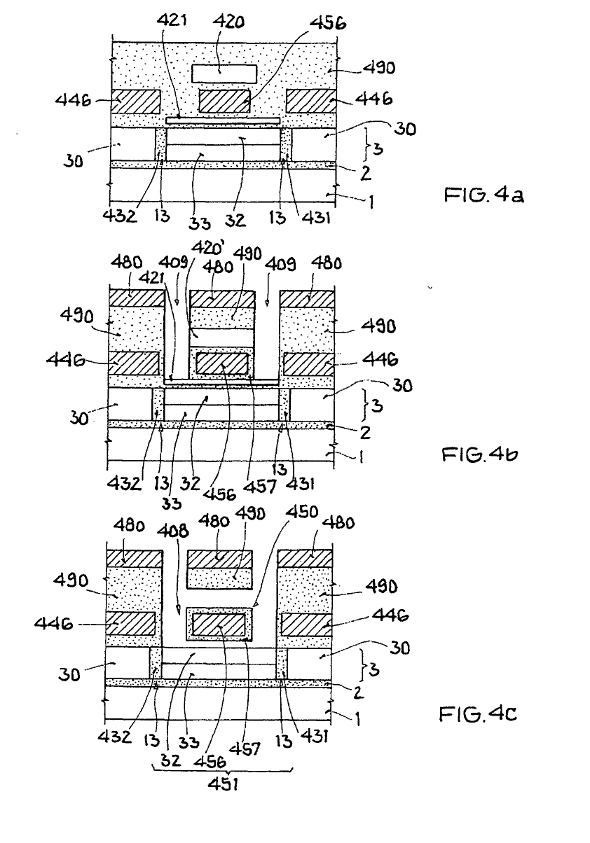

According to FIG. 4c, another exemplary embodiment for a semiconductor array with a self-supporting microstructure 450 is shown schematically in a sectional view.

A substrate 1, an isolation layer 2, and an element layer 3 with a trench structure 13 with trenches 432 and 431 are again provided. Trench structure 13 delimits a structure region 451 in the lateral direction from active regions 30 in element layer 3. Within this structure region 451, microstructure 450 is formed positioned to an opening 408. Microstructure 450 has an electrode 456 and an isolating dielectric 457.

A semiconductor array is shown with three polycrystalline silicon layers 446, buried in oxide 490, as electrodes 446 or sacrificial layers 420, 421. For example, a micromechanical resonator (MEMS resonator), in which a self-supporting rib 450 with polycrystalline silicon 456 as self-supporting microstructure 450 is driven electrostatically by the two laterally adjacent electrodes 446, is to be produced. To avoid short circuits, rib 450 has a dielectric isolation 457. Electrodes 446, distanced laterally from rib 450, are isolated by dielectric 490.

Within structure region 451, element layer 3 is doped with a dopant to form an electrode 32. A lower region 31, in contrast, can remain undoped. A micromechanical resonator is to be produced in which the capacitive coupling to the underlying electrode 32 (high-doped silicon layer) is to be improved by reducing the distance. For this reason, the oxide layer (490), lying above electrode 32, and the lower sacrificial layer 421 (cf. FIG. 4a) of polycrystalline silicon are made especially thin. The necessary nanometer distances to electrode 32 can be achieved by a sacrificial layer etching, as would not be possible laterally because of the insufficient lithographic resolution. Apart from the simple encapsulation of the structures, this can be an advantage of this exemplary embodiment.

On the basis of FIGS. 4a to 4c, the manufacturing process for producing a semiconductor array is explained hereafter in greater detail according to FIG. 4c.

According to FIG. 4a, an array with polycrystalline silicon layers 420, 421, 446, and 456 is used as the starting point. According to FIG. 4b, mask 480 is again provided. Sacrificial layer 420 of silicon is formed below mask 480.

In a first anisotropic etching step, dielectric 490 is selectively etched through openings 409 in mask 480 down to sacrificial layer 421. The dielectric etching therefore stops at this sacrificial layer 421. The edge regions of upper polycrystalline silicon layer 420, which is used later as sacrificial layer 420 to expose self-supporting microstructure 450, are exposed in particular during the etching.

An isotropic silicon etching process occurs next which removes sacrificial layers 420 and 421. This is shown in FIG. 4c. Electrode 456 of polycrystalline silicon, which is surrounded by oxide 457, and lateral electrodes 446 are preserved. Lateral electrodes 446 are not absolutely necessary for the depicted oscillator variant, because the lower electrode 32 is used. These lateral electrodes 446 can be used optionally, however, for setting the oscillation properties. An encapsulation by deposition of a thick oxide layer or the like or by bonding with a cap wafer can then occur again after the etching.

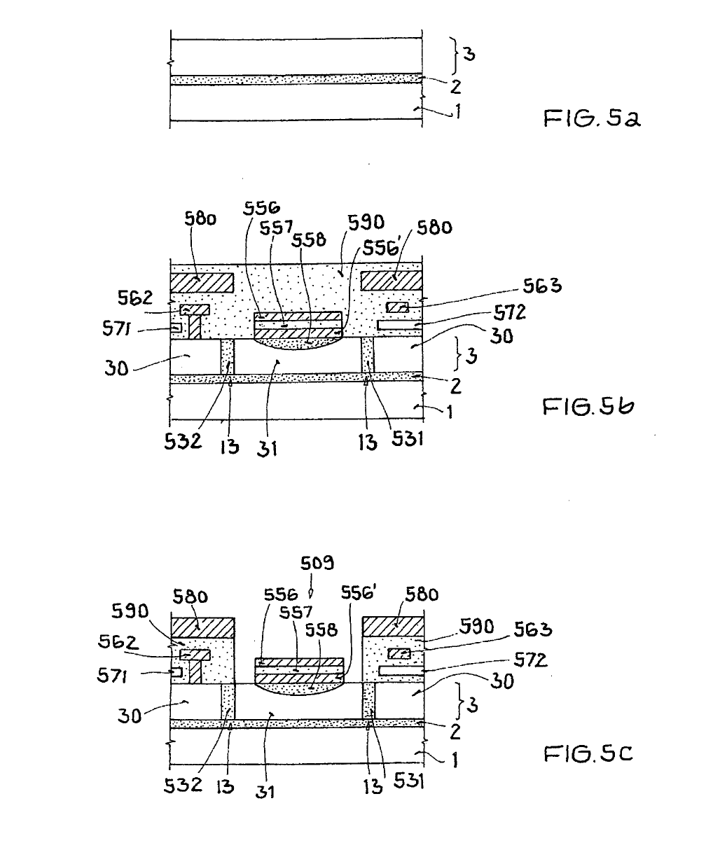

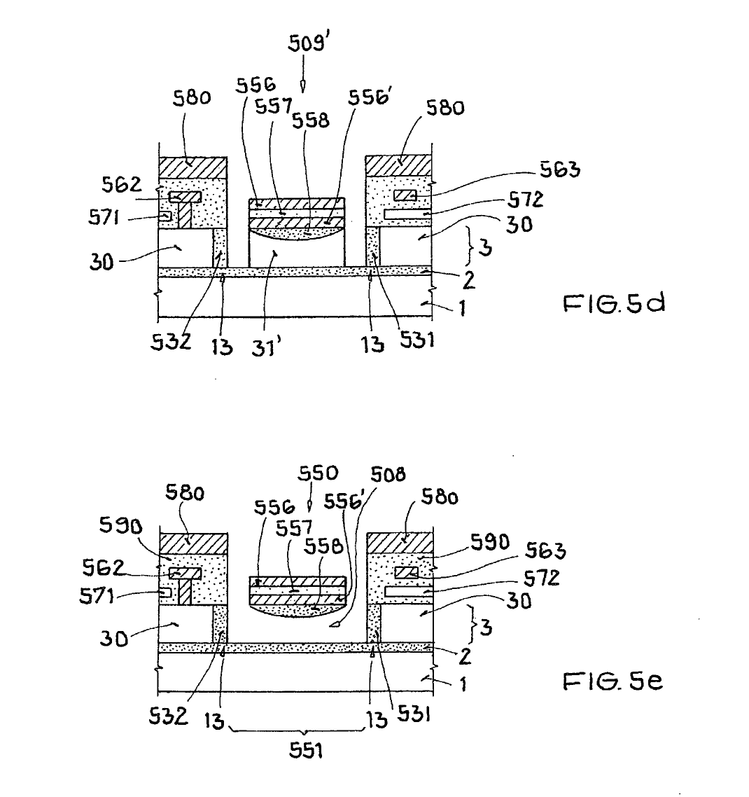

FIG. 5e shows another exemplary embodiment for a semiconductor array with a self-supporting microstructure 550 in a schematic sectional view. A substrate 1, an isolation layer 2, and an element layer 3 with a trench structure 13 with trenches 532 and 531 are again provided. Trench structure 13 delimits a structure region 551 in the lateral direction from active regions 30 in element layer 3. Within this structure region 551, microstructure 550 is formed positioned to an opening 508. Microstructure 550 has two electrodes 556 and 556′, aluminum nitride layer 557, disposed between electrodes 556 and 556′, and a flat elevation 558 of silicon dioxide. Furthermore, traces 562, 563, 572 and a gate electrode 571 are isolated from one another by a dielectric 590. The self-supporting structure is thereby formed as an FBAR (Film Bulk Acoustic Resonator). The FBAR in FIG. 5e, in this case, is formed as a thickness resonator. Alternatively, other resonators, such as an extension resonator, radial resonator, or torsion resonator can be formed.

On the basis of FIGS. 5a to 5e, the manufacturing process for producing a semiconductor array is explained hereafter in greater detail according to FIG. 5e.

Proceeding from an SOI structure according to FIG. 5a, mask 580 is again provided according to FIG. 5b. During the process for manufacturing the elements, an STI region 558 as a later support for the FBAR as well as the structured AIN layer 555 and metal electrodes 556 and 556′ are already formed. It is advantageous in this case that a planarization by means of chemical-mechanical polishing of the STI region can occur before an AIN deposition.

According to FIG. 5b, in a first anisotropic etching step, which selectively etches dielectric 590, the surface of mask 580, the surface of the one electrode 556, and the surface of sacrificial region 31 within the broad opening 509 in mask 580 are exposed. The dielectric etching therefore stops at sacrificial region 31.

An anisotropic silicon etch process then occurs into a sacrificial region 31 of element layer 3. This is shown in FIG. 5d, whereby after the anisotropic etching a residual sacrificial region 31′ remains below the later self-supporting microstructure (550, cf. FIG. 5e). This anisotropic silicon etching is used for prefabrication for the subsequent isotropic silicon etching. The etching time can be shortened in this way, because the lateral etching rate is usually lower than the vertical rate. The etching step of the anisotropic silicon etching is basically unnecessary, however, and can be replaced by a suitably longer isotropic etching of silicon 31.

Trenches 531 and 532, filled with dielectric, act as a lateral stop layer for the isotropic silicon etching, so that etching into active semiconductor regions 30 of an adjacent element does not occur. The silicon etching was to occur with a high selectivity for silicon dioxide, metal, and aluminum nitride, because small aluminum nitride regions can also be exposed in self-supporting microstructure 550. The state after the isotropic silicon etching is shown in FIG. 5e. Advantages of the exemplary embodiment of FIG. 5e are a space-saving full integration and a simple encapsulation. Minor acoustic leaks are possible also. Because of the mechanical decoupling by the air gap, self-supporting structures have a lower acoustic leak mode into the substrate.

The invention is understandably not limited to the shown exemplary embodiments, but also encompasses embodiment variants that are not shown. Thus, different features of the exemplary embodiments can be exchanged among each other or combined. Alternative embodiments provide, for example, a comb-shaped, spiral-shaped, or meander-shaped structure as the self-supporting microstructure. A planar-perforated microstructure for a simplified undercutting is also possible.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A semiconductor array comprising:
a substrate;
an element layer formed of a single-crystal semiconductor material;
an isolation layer formed between the substrate and the element layer and that isolates the element layer from the substrate;
a plurality of elements that are formed in the element layer;
a trench structure that is adjacent to the isolation layer and is completely filled with dielectric to isolate at least one element of the plurality of elements within the element layer in a lateral direction; and
a self-supporting microstructure that is formed in a structure region defined by the trench structure.

2. The semiconductor array according to claim 1, further comprising a plurality of openings in the element layer, wherein at least one opening is formed within the structure region and is limited by the trench structure.

3. The semiconductor array according to claim 1, wherein the self-supporting microstructure is displaceable in a lateral direction.

4. The semiconductor array according to claim 3, wherein the displacement of the self-supporting microstructure in the lateral direction is limited by the trench structure.

5. The semiconductor array according to claim 3, wherein the displacement of the self-supporting microstructure in the lateral direction is limited by a stop formed outside the element layer.

6. The semiconductor array according to claim 1, wherein the self-supporting microstructure is displaceable in a vertical direction.

7. The semiconductor array according to claim 6, wherein the self-supporting microstructure is displaceable in the vertical direction into at least one opening of the number of openings.

8. The semiconductor array according to claim c, wherein the vertical displacement is limited by the isolation layer or the element layer.

9. The semiconductor array according to claim 1, further comprising traces that are formed in a number of conduction levels, wherein the traces are structured to connect the plurality of elements, and wherein at least one trace of the plurality of traces is structured as an electrode of the self-supporting microstructure.

10. The semiconductor array according to claim 1, further comprising an electrode for the self-supporting microstructure, which is formed within the structure region by a doped electrode region of the element layer.

11. The semiconductor array according to claim 1, wherein the self-supporting microstructure is formed within a hermetically encapsulated cavity, and wherein the cavity is closed by a capping layer.

12. The semiconductor array according to claim 1, wherein the self-supporting microstructure has an elevation formed in a direction of the isolation layer with a cross section tapering in the direction of the isolation layer.

13. A method for manufacturing a semiconductor array, the method comprising:
providing a substrate and an element layer of a single-crystal semiconductor material, and
forming an isolation layer between the substrate and the element;
forming a plurality of elements are formed in the element layer;
filling a trench structure completely with a dielectric, such that it is formed in the element layer;
defining the trench structure by a structure region; and
forming, within the structure region that is defined by the trench structure, a self-supporting microstructure.

14. The method according to claim 13, wherein the semiconductor material of the element layer is etched to form the self-supporting microstructure within the structure region, wherein the isolation layer is a vertical etch stop layer, and/or wherein the trench structure is a lateral etch stop layer.

15. The method according to claim 13, wherein, to form the self-supporting microstructure, an etching is masked by a mask, and wherein the mask is oriented to the trench structure.

16. The method according to claim 13, wherein, to form the self-supporting microstructure within the structure region, a shallow trench, filled with dielectric or a local oxide is formed, and wherein the shallow trench, filled with dielectric or the local oxide has a cross section tapering in the direction of the substrate.

17. The method according to claims 13 wherein, to form the self-supporting microstructure, a sacrificial layer that is formed above and/or below the self-supporting microstructure, is removed to expose the self-supporting microstructure.

18. The method according to claim 13, wherein an electrode region is doped in the element layer within the structure region to form an electrode for the self-supporting microstructure.
